(19) United States
(12) Patent Application Publication
(10) Pub. No.: US 2005/0277262 A1
(43) Pub. Date: Dec. 15, 2005

(54) Method for manufacturing isolation structures in a semiconductor device

(75) Inventors: Chang-Sheng Tsao, Taipei (TW); Jung-Hui Kao, Hsin-Chu (TW); Yen-Ming Chen, Hsin-Chu (TW); Lin-June Wu, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/867,336

(22) Filed: Jun. 14, 2004

(51) Int. Cl. H01L 21/76

(52) U.S. Cl. 438/423; 438/424

(57) ABSTRACT

A method for manufacturing isolation structures in a semiconductor device includes providing a substrate with a surface. A plurality of ions are implanted below the surface of the substrate and the substrate is then annealed to form a layer below its surface. Isolation structures may then be formed in the substrate extending from the surface of the substrate to approximately the depth of the layer.

### BACKGROUND

This disclosure relates generally to semiconductor devices, and more particularly to a method for manufacturing isolation structures in a semiconductor device.

As the density of components on a semiconductor device increases, the components are placed closer and closer to each other, and the need to properly isolate these components from each other arises. Isolation structures, such as shallow trench isolation (STI) structures and deep trench isolation (DTI) structures, are employed for this task. The manufacturing of these isolation structures poses a number of problems.

Isolation structures are typically manufactured using photolithography methods known in the art, followed by a time controlled etching process. Such time controlled etching processes are imprecise, resulting in poor control of the depth of the isolation trenches, which can narrow the tolerance ranges available to other parameters of device manufacture. In addition, the isolation trenches within a wafer will not be of a uniform depth, which can result in some trenches being too shallow and not isolating the components properly. These problems can lower the performance of the device. Furthermore, isolation trenches from wafer to wafer and from wafer lot to wafer lot cannot be made of a uniform depth, reducing the repeatability of device performance across wafers and wafer lots.

Accordingly, it would be desirable to provide an improved method for manufacturing isolation structures in a semiconductor device absent the disadvantages found in the prior methods discussed above.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a cross sectional view illustrating an embodiment of the method with ions being implanted below the surface of a substrate.

FIG. 2 is a cross sectional view illustrating an embodiment of the method with a layer formed below the surface of a substrate.

FIG. 3 is a cross sectional view illustrating an embodiment of the method with a layer of photoresist formed on the surface of a substrate.

FIG. 4 is a cross sectional view illustrating an embodiment of the method with light shined through a patterned mask and onto a layer of photoresist on the surface of a substrate.

FIG. 5 is a cross sectional view illustrating an embodiment of the method with sections of photoresist removed from the surface of a substrate.

FIG. 6 is a cross sectional view illustrating an embodiment of the method with isolation structures formed in a substrate.

FIG. 7 is a cross sectional view illustrating an embodiment of the method with a layer of photoresist formed on the surface of a substrate.

FIG. 8 is a cross sectional view illustrating an embodiment of the method with light shined through a patterned mask and onto a layer of photoresist on the surface of a substrate.

FIG. 9 is a cross sectional view illustrating an embodiment of the method with sections of photoresist removed from the surface of a substrate.

FIG. 10 is a cross sectional view illustrating an embodiment of the method with ions being implanted below the surface of a substrate through areas of the surface not covered with photoresist.

FIG. 11 is a cross sectional view illustrating an embodiment of the method with a sectional layer formed below the surface of a substrate.

FIG. 12 is a cross sectional view illustrating an embodiment of the method with light shined through a patterned mask and onto a layer of photoresist on the surface of a substrate.

FIG. 13 is a cross sectional view illustrating an embodiment of the method with sections of photoresist removed from the surface of a substrate.

FIG. 14 is a cross sectional view illustrating an embodiment of the method with isolation structures formed in a substrate.

### DETAILED DESCRIPTIONS

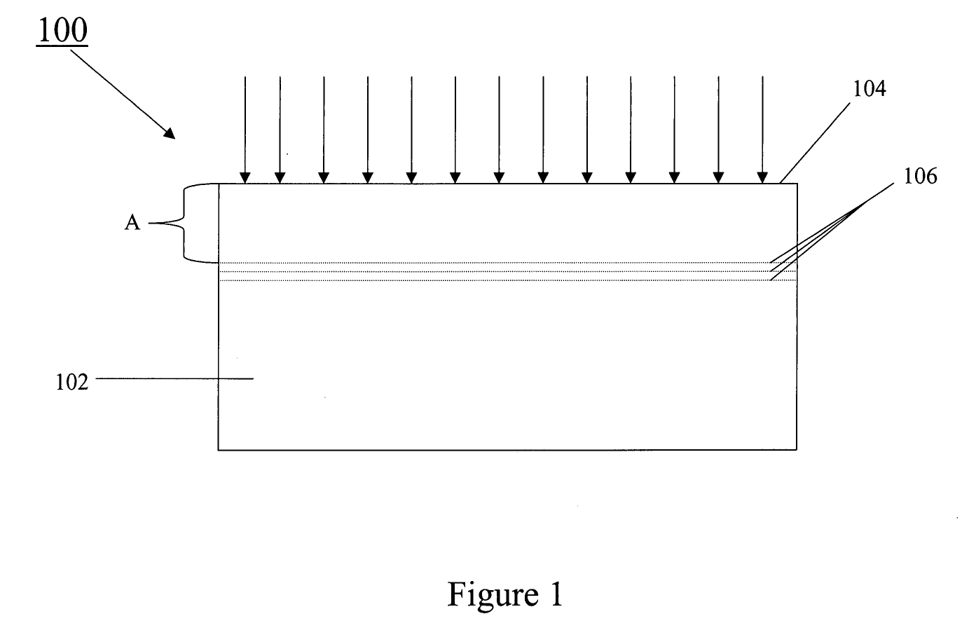

Referring to FIG. 1, a semiconductor device 100 includes a substrate 102 with a surface 104. A plurality of ions 106 are implanted approximately a distance A below the surface 104 of substrate 102. The plurality of ions 106 may be implanted using methods known in the art, such as Separation by Implantation of Oxygen (SIMOX) technology, and can be ions of a variety of elements including, but not limited to, oxygen ions, nitrogen ions, and combinations thereof. For example, an implantation of oxygen ions into a P-type substrate may exhibit a concentration of less than 1.4×10¹⁷ O⁺ ions/cm²

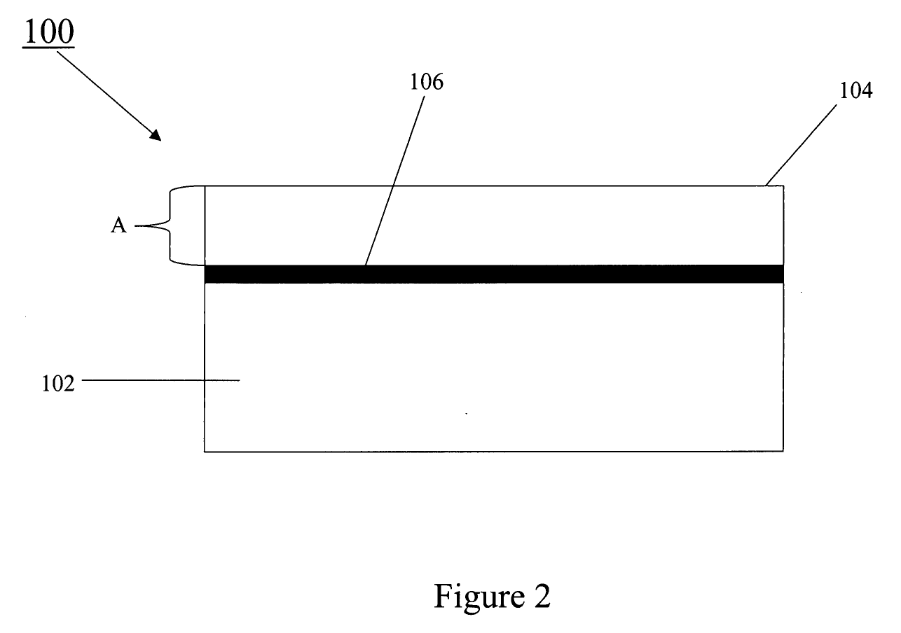

Referring now to FIG. 2, following the ion implantation, device 100 is annealed. Annealing device 100 results in the growth of a layer 106 approximately a distance A below the surface 104 of substrate 102. Depending on the type of ions implanted and the substrate used, layer 106 may be composed of a number of materials including, but not limited to, SiO₂, SiN, and SiOₓN_{y}. For example, an annealing of oxygen ions implanted in a P-type substrate may occur below 1300 degrees C. to grow layer 106 to a thickness of 200-400 A.

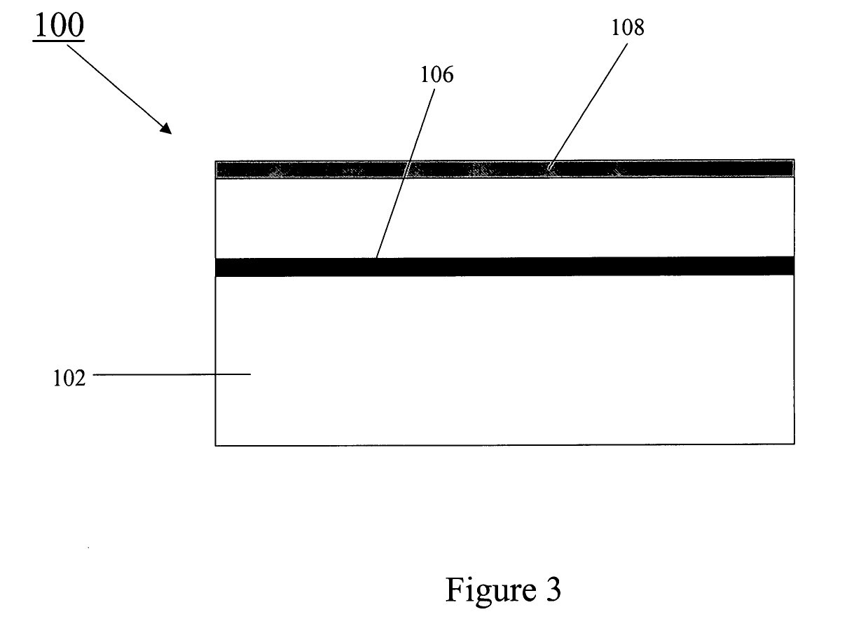

Referring now to FIG. 3, a layer of photoresist 108 is deposited on surface 104 of substrate 102. Photoresist 108 may be deposited using methods known in the art.

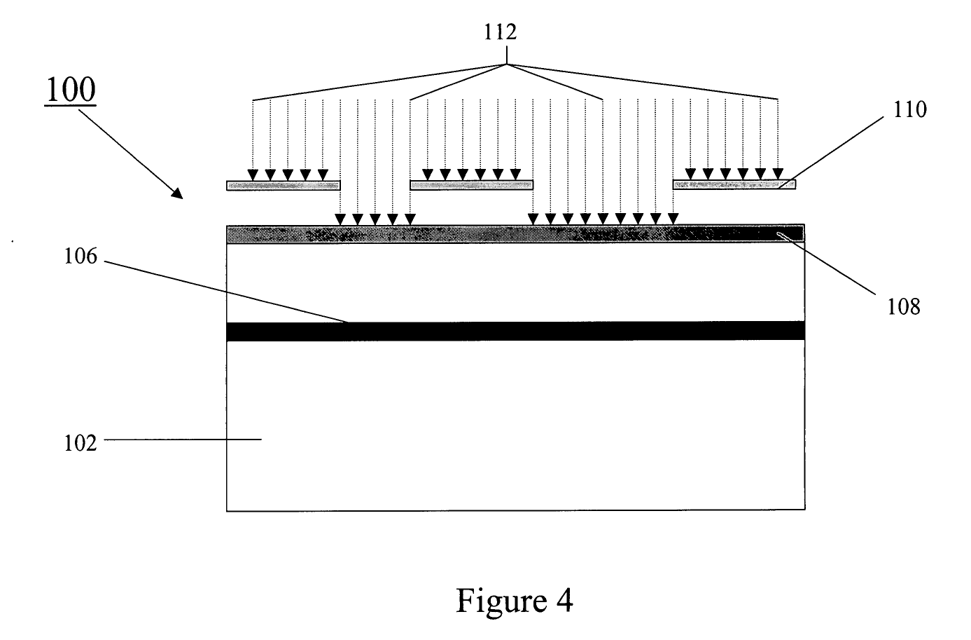

Referring now to FIG. 4, a patterned mask 110 is placed over the layer of photoresist 108, and a light 112 is shined on the patterned mask 110. Light 112 passes through sections of patterned mask 110 and onto photoresist 108. Physical properties of photoresist 108 are changed by exposure to light 112.

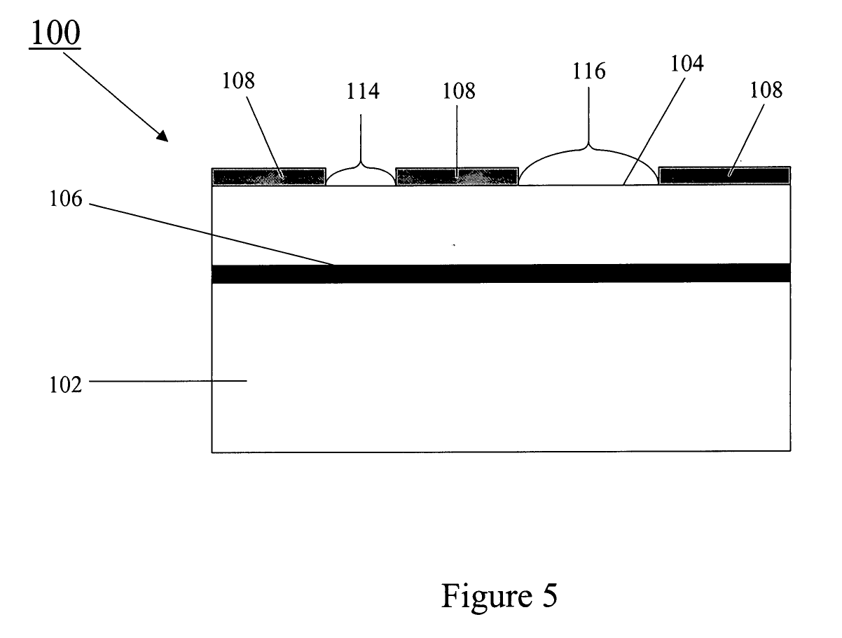

Referring now to FIG. 5, the photoresist 108 is developed, which removes section of photoresist 108 from surface 104 which have been exposed to light 112, exposing a surface section 114 and 116 on substrate 102. Alternative types of photoresist 108 may be used such that development would remove sections of photoresist 108 from the surface 104 of substrate 102 which had not been exposed to light 112.

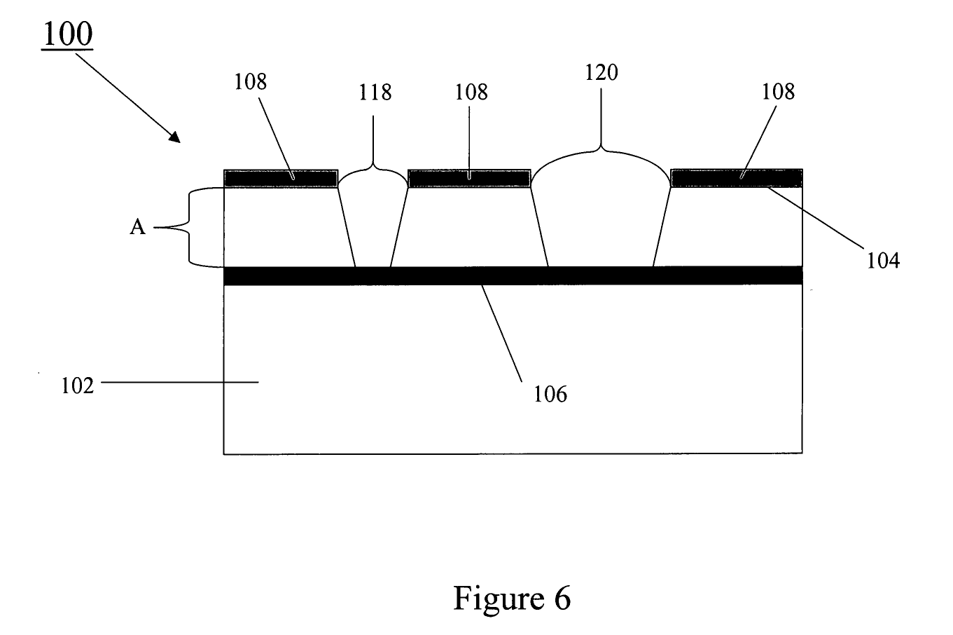

Referring now to FIG. 6, following the removal of photoresist 108 from surface 104 of substrate 102, an isolation structure 118 and an isolation structure 120 may be etched into substrate 102 through the exposed portions of surface 104, such as sections 114 and 116 as illustrated in FIG. 5, on substrate 102 using methods known in the art. However, the etchant will be stopped by layer 106, which will provide isolation structures 118 and 120 of approximately the same depth A. In an exemplary embodiment, the isolation structures 118 and 120 may be shallow trench isolation structures, which include isolation structures exhibiting a depth with a range of approximately 0.1 to approximately 5 μm. In an exemplary embodiment, the isolation structures 118 and 120 may be shallow trench isolation structures, which include isolation structures exhibiting a depth with a range of approximately 0.1 to approximately 5 μm.

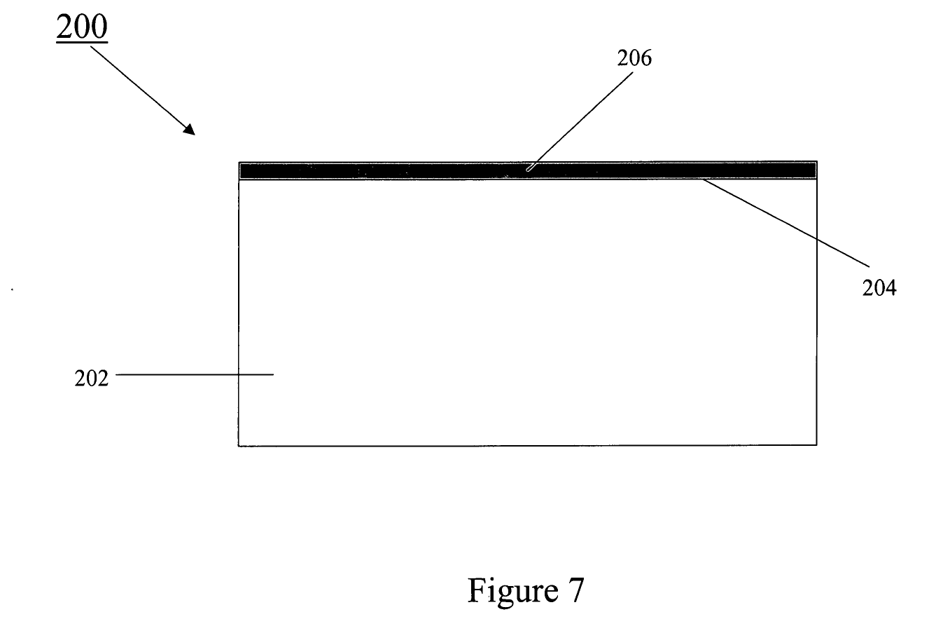

Referring now to FIG. 7, in an alternative embodiment, a semiconductor device 200 includes a substrate 202 with a surface 204. A layer of photoresist 206 is deposited on surface 204 of substrate 202. Photoresist 206 may be deposited using methods known in the art.

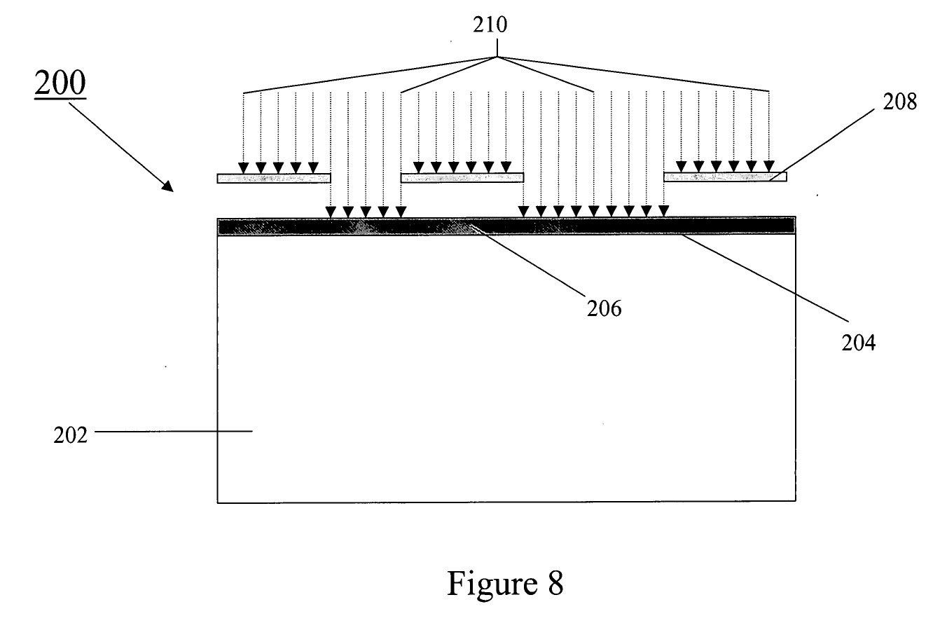

Referring now to FIG. 8, a patterned mask 208 is placed over the layer of photoresist 206, and a light 210 is shined on the patterned mask 208. Light 210 passes through sections of patterned mask 208 and onto photoresist 206. Physical properties of photoresist 204 are changed by exposure to light 210.

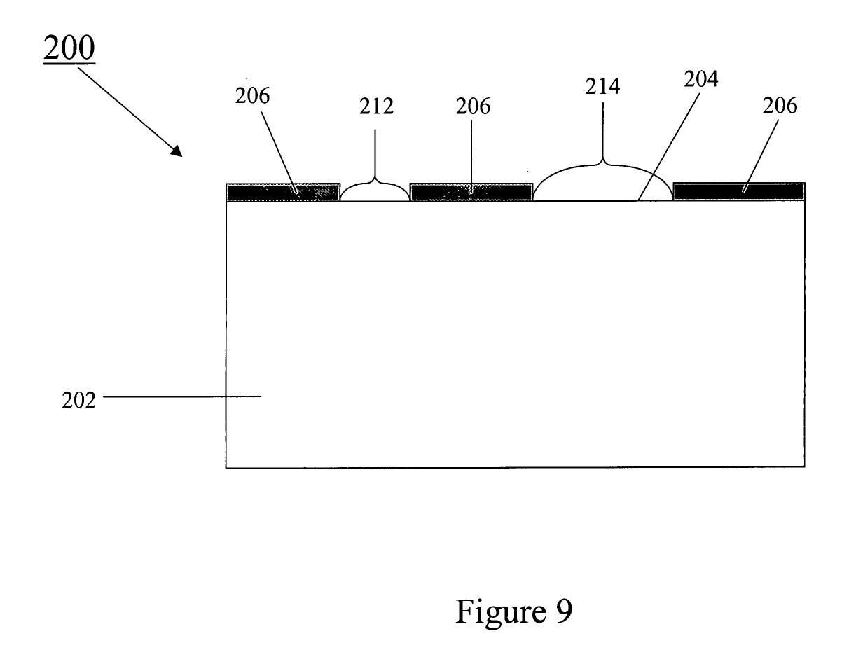

Referring now to FIG. 9, the photoresist 206 is developed which removes section of photoresist 206 from surface 204 which have been exposed to light 210, exposing a surface section 212 and 214 on substrate 202. Alternative types of photoresist 206 may be used such that development would remove sections of photoresist 206 from the surface 204 of substrate 202 which had not been exposed to light 210.

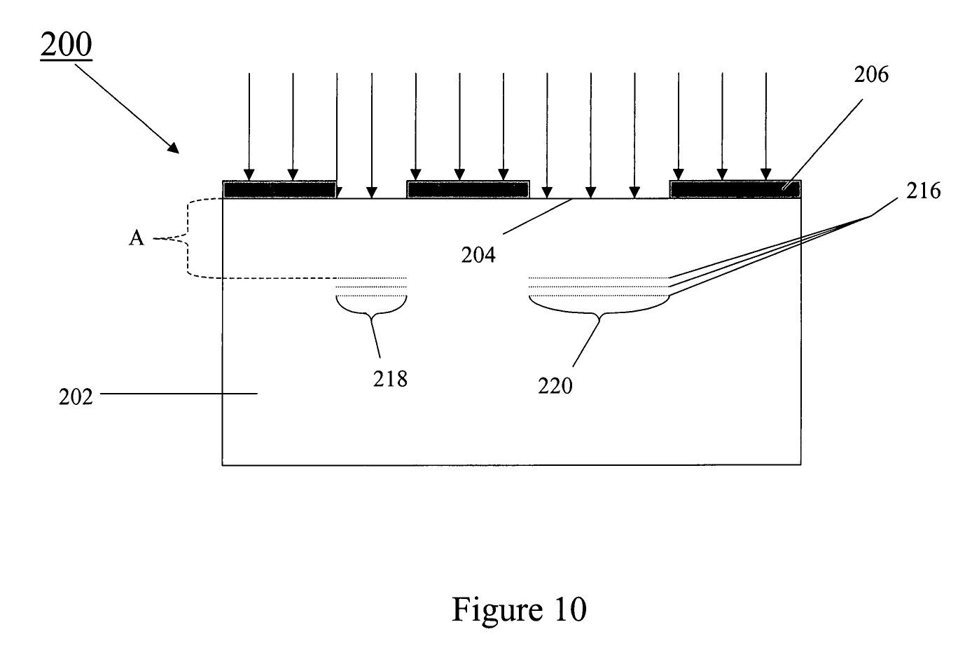

Referring now to FIG. 10, a plurality of ions 216 are implanted approximately a distance A below the surface 204 of substrate 202. The plurality of ions 216 are implanted through the exposed surface 204, such as sections 212 and 214 as illustrated in FIG. 9, of substrate 202, resulting in implanted ion sections 218 and 220. The plurality of ions 216 may be implanted using methods known in the art, such as Separation by Implantation of Oxygen (SIMOX) technology, and can be ions of a variety of elements including, but not limited to, oxygen ions, nitrogen ions, and combinations thereof. For example, an implantation of oxygen ions into a P-type substrate may exhibit a concentration of less than 1.4×10¹⁷ O⁺ ions/cm².

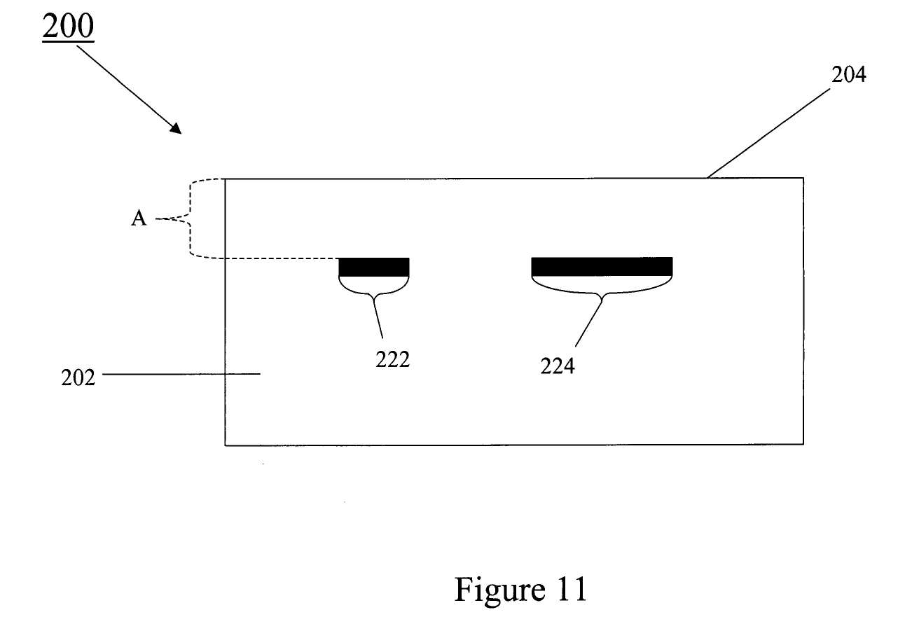

Referring now to FIG. 11, the photoresist 206 is removed from surface 204 of substrate 202 and device 200 is annealed. Annealing the device 200 results in the growth of a layer section 222 and 224 approximately a distance A below the surface 204 of substrate 202. Depending on the type of ions implanted and the substrate used, layer section 222 and 224 may be composed of a number of materials including, but not limited to, SiO₂, SiN, and SiOₓN_{y}. For example, an annealing of oxygen ions implanted in a P-type substrate may occur below 1300 C to grow layer sections 222 and 224 to a thickness of 200-400 A.

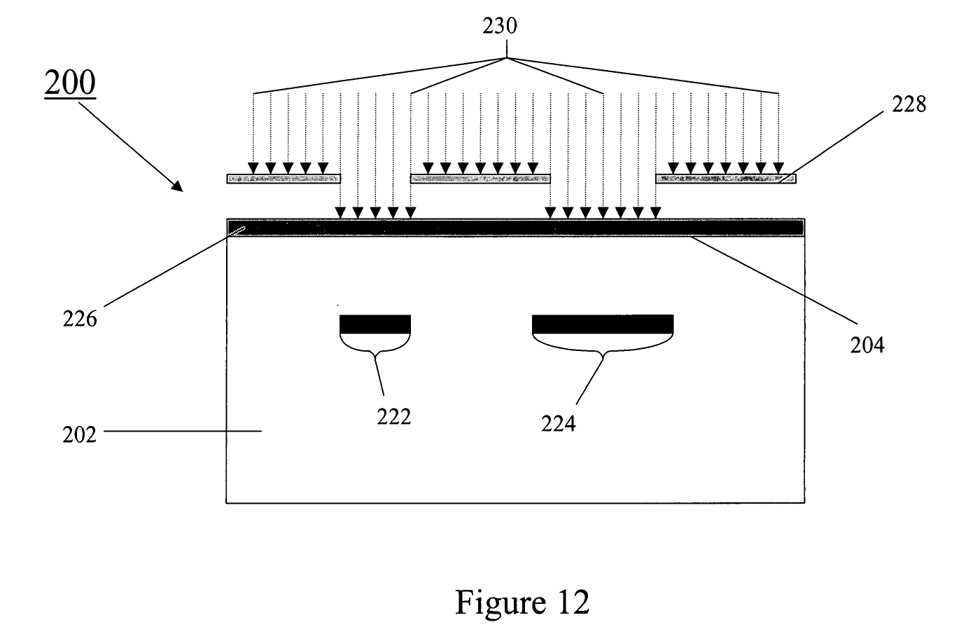

Referring now to FIG. 12, after growth of layer sections 222 and 224, a layer of photoresist 226 is deposited on the surface 204 of substrate 202. A patterned mask 228 is placed over the layer of photoresist 226 and a light 230 is shined on the patterned mask 228. Light 230 passes through sections of patterned mask 228 and onto photoresist 226. Physical properties of photoresist 226 are changed by exposure to light 230.

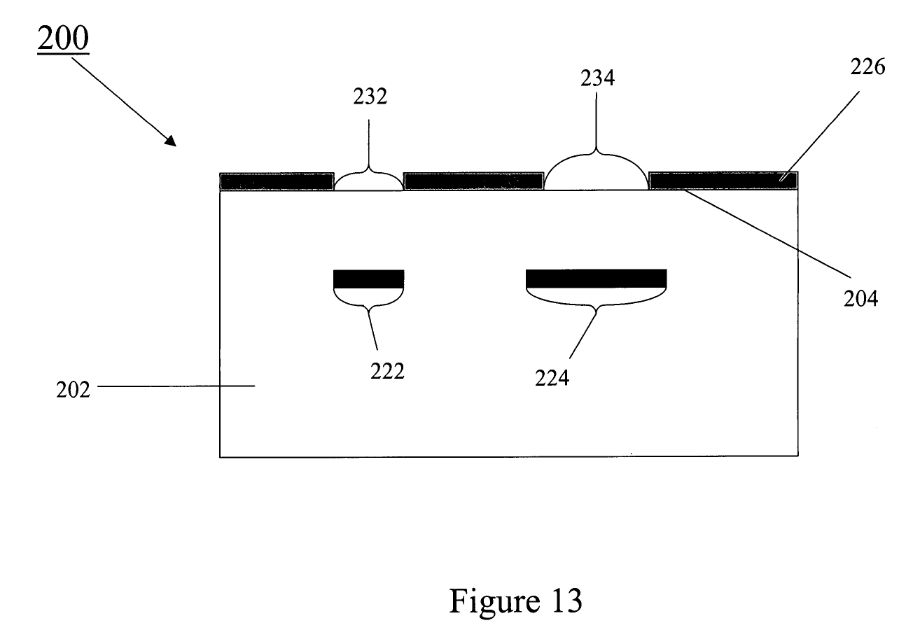

Referring now to FIG. 13, photoresist 226 is developed, which removes sections of photoresist 226 from surface 204 which have been exposed to light 230, exposing a surface section 232 and 234 on substrate 202. Alternative types of photoresist 226 may be used such that development would remove sections of photoresist 226 from the surface 204 of substrate 202 which had not been exposed to light 230.

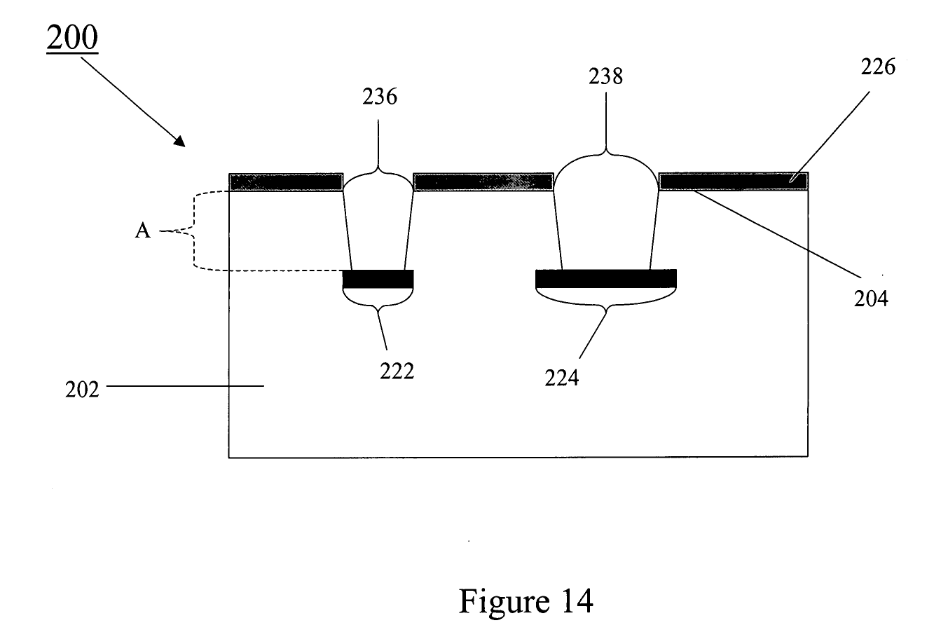

Referring now to FIG. 14, following the removal of photoresist 226 from surface 204 of substrate 202, an isolation structure 236 and an isolation structure 238 may be etched into substrate 202 through the exposed portions of surface 204, such as sections 232 and 234 as illustrated in FIG. 13, on substrate 202 using methods known in the art. However, the etchant will be stopped by layer sections 222 and 224, which will provide isolation structures 236 and 238 of approximately the same depth A. In an exemplary embodiment, the isolation structures 236 and 238 may be shallow trench isolation structures, which include isolation structures exhibiting a depth with a range of approximately 0.1 to approximately 5 μm. In an exemplary embodiment, the isolation structures 236 and 238 may be shallow trench isolation structures, which include isolation structures exhibiting a depth with a range of approximately 0.1 to approximately 5 μm.

It is understood that variations may be made in the foregoing without departing from the scope of the invention. Furthermore, the elements and teachings of the various illustrative embodiments may be combined in whole or in part some or all of the illustrative embodiments.

Although only a few exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention as defined in the following claims.

1. A method for manufacturing isolation structures in a semiconductor device comprising:
providing a substrate with a surface;
implanting a plurality of ions below the surface of the substrate;
annealing the substrate to form a layer below the surface of the substrate; and
forming at least one isolation structure in the substrate extending to approximately the depth of the layer.

2. The method of claim 1 wherein the plurality of ions are implanted approximately a uniform depth below the surface.

3. The method of claim 1 wherein the layer is formed at approximately a uniform depth below the surface.

4. The method of claim 1 wherein the at least one isolation structure includes a shallow trench isolation structure.

5. The method of claim 1 wherein the at least one isolation structure includes a deep trench isolation structure.

6. The method of claim 1 wherein the layer includes an etch stop layer.

7. The method of claim 1 wherein the substrate includes silicon.

8. The method of claim 1 wherein the plurality of ions are selected from the group consisting of oxygen ions, nitrogen ions, and a combination thereof.

9. The method of claim 7 wherein the plurality of ions include oxygen ions.

10. The method of claim 9 wherein the layer which is formed includes SiO₂.

11. A method for manufacturing isolation structures in a semiconductor device comprising:
providing a substrate with a surface;
forming a patterned layer on the surface, the patterned layer including openings that expose the substrate surface;
implanting a plurality of ions below the surface of the substrate through the openings in the patterned layer;
annealing the substrate to form at least one stop layer below the surface of the substrate; and
forming at least one isolation structure in the substrate extending to approximately the depth of the at least one stop layer.

12. The method of claim 11 wherein the plurality of ions are implanted below the surface at approximately a uniform depth.

13. The method of claim 11 wherein the at least one stop layer is formed at approximately a uniform depth below the surface.

14. The method of claim 11 wherein the at least one isolation structure includes a shallow trench isolation structure.

15. The method of claim 11 wherein the at least one isolation structure includes a deep trench isolation structure.

16. The method of claim 11 wherein the at least one stop layer includes an etch stop layer.

17. The method of claim 11 wherein the substrate includes silicon.

18. The method of claim 11 wherein the plurality of ions are selected from the group consisting of oxygen ions, nitrogen ions, and a combination thereof.

19. The method of claim 17 wherein the plurality of ions include oxygen ions.

20. The method of claim 19 wherein the at least one stop layer which is formed includes a SiO₂ layer.

21. A method for manufacturing isolation structures in a semiconductor device comprising:
providing a substrate with a surface;
implanting a plurality of ions at substantially a uniform depth below the surface of the substrate;
annealing the substrate to cause the plurality of ions to react with the substrate and form an etch stop layer at approximately a uniform depth below the surface of the substrate;
etching a plurality of trenches into the surface of the substrate to a depth of approximately the etch stop layer;
forming a plurality of isolation structures from the trenches in the substrate, whereby the isolation structures exhibit an approximately uniform depth.

22. The method of claim 21 wherein the plurality of isolation structures includes shallow trench isolation structures.

23. The method of claim 21 wherein the plurality of ions are selected from the group consisting of oxygen ions, nitrogen ions, and a combination thereof.
